(19) United States
(12) Patent Application Publication
(10) Pub. No.: US 2019/0158209 A1
(43) Pub. Date: May 23, 2019

(54) WAVELENGTH DEMULTIPLEXER

(71) Applicant: Intel Corporation, Santa Clara, CA (US)

(72) Inventors: Wenhua Lin, Fremont, CA (US); Judson Douglas Ryckman, Dayton, OH (US); Ling Liao, Fremont, CA (US); Kelly Christopher Magruder, Albuquerque, NM (US); Harel Frish, Albuquerque, NM (US); Assia Barkai, Jerusalem (IL); Han-din Liu, Sunnyvale, CA (US); Yimin Kang, San Jose, CA (US)

(73) Assignee: Intel Corporation, Santa Clara, CA (US)

(21) Appl. No.: 16/236,125

(22) Filed: Dec. 28, 2018

(51) Int. Cl. H04J 14/02; H04B 10/572; H04B 10/50; H01S 5/40; G02B 6/42; G02B 6/12

(52) U.S. Cl. CPC H04J 14/0246; H04B 10/572; H04B 10/506; H04J 14/0221; G02B 6/12007; H04J 14/0298; H01S 5/4025; G02B 6/4204; H04J 14/0278

(57) ABSTRACT

There is disclosed in one example a fiberoptic communication circuit for wavelength division multiplexing (WDM) communication, including: an incoming waveguide to receive an incoming WDM laser pulse; an intermediate slab including a demultiplexer circuit to isolate n discrete modes from the incoming WDM laser pulse; n outgoing waveguides to receive the n discrete modes, the outgoing waveguides including fully-etched rib-to-channel waveguides; and an array of n photodetectors to detect the n discrete modes.

### FIELD OF THE SPECIFICATION

This disclosure relates in general to the field of fiberoptic communication, and more particularly, though not exclusively, to a system for providing a wavelength demultiplexer.

### BACKGROUND

Wavelength division multiplexing (WDM) is a communication technique of multiplexing a plurality of optical carrier signals onto a single optical fiber. A plurality of wavelengths of laser light are multiplexed onto the single optical fiber, thus providing discrete communication over a plurality of channels on the single optical fiber.

### BRIEF DESCRIPTION OF THE DRAWINGS

The present disclosure is best understood from the following detailed description when read with the accompanying figures. It is emphasized that, in accordance with the standard practice in the industry, various features are not necessarily drawn to scale, and are used for illustration purposes only. Where a scale is shown, explicitly or implicitly, it provides only one illustrative example. In other embodiments, the dimensions of the various features may be arbitrarily increased or reduced for clarity of discussion.

FIG. 1 is a block diagram of an optoelectronic system that may include a multiplexer and/or demultiplexer manufactured with a rib-channel converter of the present specification.

FIG. 2 is an example embodiment of the optoelectronic system as an integrated photonics link.

FIG. 3 is a block diagram of an echelle grating (EG)-based wavelength demultiplexer (DEMUX).

FIG. 4 illustrates a waveguide manufactured according to an existing rib technique.

FIGS. 5A-5D illustrate the relationship between rib etch depth and inter-mode isolation.

FIGS. 6 and 7 illustrate the realization of experimental results from a completely etched channel waveguide prototype.

FIG. 8 illustrates selected aspects of a rib-to-channel converter.

FIGS. 9A and 9B illustrate two examples of a DEMUX layout.

FIG. 10 illustrates additional details of a layout schematic, including a 3D schematic and a top-view layout.

FIG. 11 is a block diagram of selected components of a data center with network connectivity.

FIG. 12 is a block diagram of selected components of an end-user computing device.

FIG. 13 is a block diagram of components of a computing platform.

FIG. 14 is a flowchart of an etching process.

### EMBODIMENTS OF THE DISCLOSURE

The following disclosure provides many different embodiments, or examples, for implementing different features of the present disclosure. Specific examples of components and arrangements are described below to simplify the present disclosure. These are, of course, merely examples and are not intended to be limiting. Further, the present disclosure may repeat reference numerals and/or letters in the various examples, or in some cases across different figures. This repetition is for the purpose of simplicity and clarity and does not in itself dictate a specific relationship between the various embodiments and/or configurations discussed. Different embodiments may have different advantages, and no particular advantage is necessarily required of any embodiment.

A contemporary computing platform may include a complex and multi-faceted hardware platform provided by Intel®, another vendor, or combinations of different hardware from different vendors. For example, a large data center such as may be provided by a cloud service provider (CSP), a high-performance computing (HPC) cluster, or a hardware platform may include rack-mounted servers with compute resources such as processors, memory, storage pools, accelerators, and other similar resources. As used herein, “cloud computing” includes network-connected computing resources and technology that enables ubiquitous (often worldwide) access to data, resources, and/or technology. Cloud resources are generally characterized by flexibility to dynamically assign resources according to current workloads and needs. This can be accomplished, for example, by assigning a compute workload to a guest device, wherein resources such as hardware, storage, and networks are provided to a virtual machine, container, or disaggregated node by way of nonlimiting example.

In embodiments of the present disclosure, a processor includes any programmable logic device with an instruction set. Processors may be real or virtualized, local or remote, or in any other configuration. A processor may include, by way of nonlimiting example, an Intel° processor (e.g., Xeon®, Core™, Pentium®, Atom®, Celeron®, x86, or others). A processor may also include competing processors, such as AMD (e.g., Kx-series x86 workalikes, or Athlon, Opteron, or Epyc-series Xeon workalikes), ARM processors, or IBM PowerPC and Power ISA processors, to name just a few.

Wavelength division multiplexing (WDM) in optical networks is a significant technology for fiberoptic backbones. These are particularly useful in data center interconnects for long distance data transmission. In WDM, the information-bearing signal is transmitted by modulating an optical source of a semiconductor laser either internally (direct modulation) or externally (using an external modulator). The transmitted signal travels down the optical fiber and is detected by one or more photodetectors at the receiving end. A significant concern in WDM networks is crosstalk or other interference between the different communication channels in the single optical fiber.

Optical multiplexer/demultiplexer devices based on echelle grating techniques may be used to realize multiplexing or demultiplexing of optical signals. Different approaches may be used to increase reflectivity of the grating surface in these devices, and therefore reduce optical loss. For example, metal may be deposited onto the grating surface to enhance reflectivity. In another example, distributed Bragg reflector (DBR) mirrors may be fabricated behind the grating surface. In yet another example, straight grating facets may be replaced by corner mirror structures in the grating surface.

Optical multiplexers (MUXes) and demultiplexers (DEMUXes) are integral components in WDM networks for optical communications and interconnects. To propagate multiple wavelengths, with each wavelength representing a discrete channel, down a single optical fiber, the wavelengths are multiplexed (i.e., combined) by a MUX at one end of the fiber, and demultiplexed (i.e., separated) by a DEMUX at the receiving end. Optical MUX and DEMUX elements, such as an echelle grating (EG) or arrayed waveguide (AWG), may integrate well with other optical components like lasers and detectors to form a highly integrated, monolithic photonic integrated circuit (PIC).

In common usage, a PIC is a structure in which an electromagnetic (EM) wave may be generated and modulated to encode information into the wave. Some structural elements of a PIC include an EM source (which may include a laser or oscillator, by way of nonlimiting example), modulators for encoding information, and EM signal launchers that act as impedance converters (at the low end of the EM spectrum) or as either convergent or divergent lenses (at light frequencies). The EM signal launchers are designed to efficiently launch either electronic or photonic EM signals into the medium of propagation, and may additionally perform frequency or wavelength multiplexing. As used in the present specification, a PIC may be understood generally as pertaining to EM waves in the optical wavelength.

The optical crosstalk contribution due to demultiplexing channels into each photodetector is significant for a WDM system. When signals from one wavelength channel arrive in another, they become noise in the other wavelength channel in a DEMUX. This is known as crosstalk. Crosstalk increases the bit error rate (BER) of the system, while the optical signal-to-noise ratio (OSNR), including crosstalk, degrades. To reduce the BER to the baseline without any crosstalk, some existing systems increase signal power to remove the OSNR. This means more power is sacrificed at the input to provide a cleaner signal at the output. This may be referred to as a “power penalty.” During design, crosstalk may generally be illustrated as a “worst-case” condition, which is important, for example, for pulse amplitude modulation with four amplitude levels (PAM4) and high data rate requirements in optical networks.

One solution for providing low-cost and power-efficient high speed optical interconnects for data centers is silicon (Si) photonics. Si photonics realizes advantages in terms of manufacturability and scalability. However, there are challenges in manufacturing a silicon or a silicon nitride (Si₃N₄)-based DEMUX to meet optical crosstalk requirements. In some cases, these challenges are driven by the wide spectral bandwidth required to support the un-cooled laser operation, especially for high data rate systems.

Some existing flat-top DEMUX solutions use a single waveguide structure at the input and output to moderate crosstalk in either the echelle grating or the AWG-based DEMUX. Alternatively, a discrete thin-film filter (TFF) technology also provides good channel isolation crosstalk. However, it may be difficult to integrate TFF technology with the Si photonics process.

Thus, existing solutions in EG or AWG fabrication encounter challenges in meeting low channel isolation in the DEMUX, because of physical limits on the waveguide pitch and the resulting large chip sizes. This may result in a low figure of merit (FOM) in the DEMUX. In the case of TFF, the technology may be difficult to integrate into Si photonics.

Embodiments of the present specification provide a fully-etched channel, which provides low crosstalk between transmission modes with reduced power, relative to partially-etched rib configurations. The present specification also provides a rib-to-channel converter structure that may be used in construction of a fully-etched channel during fabrication of an integrated circuit. The result of the fully-etched channel is a communication waveform having an excellent square box, flat-top spectrum with low DEMUX loss and improved performance.

The rib-to-channel converter of the present specification may be manufactured using a double-etching process for the DEMUX input and/or output ports. This isolates the waveguide mode leakages to neighboring waveguide modes, significantly reducing adjacent channel crosstalk. The result is a square box-like flat-top spectral response with wider bandwidth and a higher FOM. Different configurations may be applied along the DEMUX device and the integrated receiver chips.

Advantageously, a DEMUX manufactured according to the teachings of the present specification allows un-cooled laser operation over the industrial or wide temperature range in 4-channel coarse wavelength division multiplexing (CWDM) optical systems. The DEMUX of the present specification also reduces adjacent channel crosstalk in the DEMUX, thus improving the OSNR in the transmission line, and reducing the power penalty in WDM optical transmission links.

A prototype of the DEMUX of the present specification has been tested experimentally, and achieved improvement of optical crosstalk by 3 to 6 dB, making a square box spectra and improving FOM from approximately 0.4 to approximately 0.6. This is approximately 1 dB to 20 dB ratio bandwidth. A similar design can be implemented in other receiver-end products.

Advantageously, a fabrication process of the DEMUX of the present specification is compatible with existing complementary metal-oxide-semiconductor (CMOS) processes that are used to make other devices. This helps to provide a low-cost solution for an integrated DEMUX receiver for transceiver products.

A system and method for providing a wavelength demultiplexer will now be described with more particular reference to the attached FIGURES. It should be noted that throughout the FIGURES, certain reference numerals may be repeated to indicate that a particular device or block is wholly or substantially consistent across the FIGURES. This is not, however, intended to imply any particular relationship between the various embodiments disclosed. In certain examples, a genus of elements may be referred to by a particular reference numeral (“widget 10”), while individual species or examples of the genus may be referred to by a hyphenated numeral (“first specific widget 10-1” and “second specific widget 10-2”).

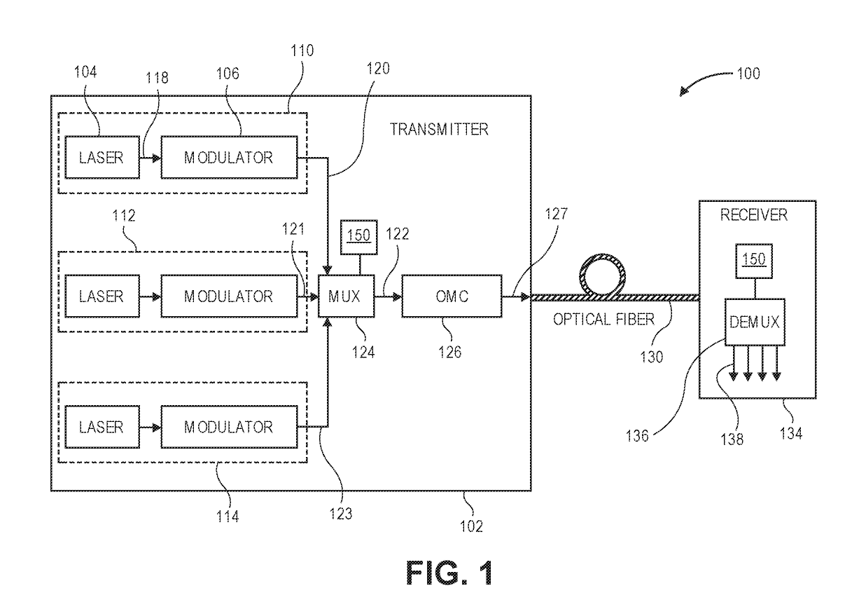

FIG. 1 is a block diagram of an optoelectronic system 100 that may include a multiplexer and/or demultiplexer manufactured with a rib-channel converter of the present specification. The optoelectronic system 100 may be used to transmit an optical signal modulated with a data signal via an optical fiber, for example, between racks in a data center, or long distance, between data storage facilities, data centers, and the like.

The optoelectronic system 100 may include an optical device such as transmitter 102 (e.g., a photonic chip). The transmitter 102 may include one or more light sources (e.g., laser devices) 104 to provide a light signal 118 (e.g., constant light intensity signal) to a respective modulator 106 to modulate input light according to a data signal to be transmitted. Each combination of a light source 104 and corresponding modulator 106 may comprise a communication channel 110, 112, or 114. Although three communication channels are shown, fewer or multiple more communication channels may be used in a transmitter such as 102 to provide, for example, a desired data transmission rate. The modulator 106 may output a modulated optical signal 120 to a multiplexer 124 having a mirror 150 with echelle grating providing a substantially total internal reflection of light as described herein. Similarly, communication channels 112 and 114 may output modulated signals 121 and 123 to the multiplexer 124. Signals 120, 121, and 123 multiplexed from communication channels 110, 112, and 114 may be input as a combined signal 122 to an optical mode converter (e.g., a coupler) 126.

The optical mode converter 126 may provide the interface from multiplexer 124 with mirror 150 on the photonic chip to an optical communication channel (e.g., optical fiber cable) 130 and is configured to transfer the combined optical signal 127 to the optical communication channel 130, to be received by a receiver 134. In embodiments, the receiver 134 may include a demultiplexer 136 having a mirror 150 with echelle grating providing a substantially total internal reflection of light as described herein. The demultiplexer 136 may be configured to demultiplex signal 127 into multiple signals 138, according to techniques described herein.

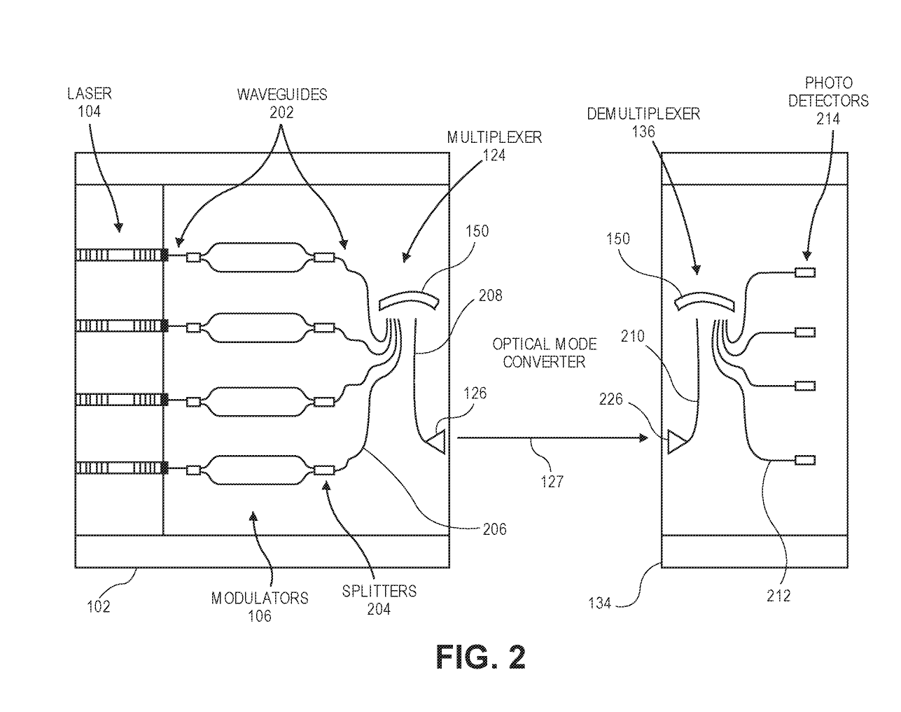

FIG. 2 is an example embodiment of the optoelectronic system as an integrated photonics link 200. Similar to the system 100 described above, the link 200 may include a transmitter 102 and receiver 134. The transmitter 102 may include multiple lasers 104 and waveguides 202 comprising modulators 106 and splitters 204. The optical signals generated by the lasers 104 may be provided through the waveguides 202 and splitters 204 to the mirror 150 of the multiplexer 124 with multiple input waveguides 206, according to wavelengths of each of the waveguides 206. The mirror 150 may substantially totally reflect the optical signals of different wavelengths and combine the signals due to the echelle grating effect of the mirror. An output waveguide 208 may receive the combined optical signal and transmit the optical signal to the optical mode converter 126. The optical mode converter 126 may provide the optical signal 127 converted from the combined optical signal to the receiver 134, to be converted by an optical mode converter 226 of the receiver 134. The converted optical signal may then be input into the demultiplexer 136 with the mirror 150 via the input waveguide 210.

Mirror 150 may substantially totally reflect the optical signal, which may be split by wavelengths due to the echelle grating effect of mirror 150. The split portions of the signal may be received by multiple output waveguides 212 according to corresponding wavelengths of the waveguides 212. The portions of the output signal may be provided via the output waveguides 212 to photodetectors 214, to be further processed as desired. Various embodiments of the multiplexer 124 or demultiplexer 136 having the mirror 150 with echelle grating surface providing substantially total internal reflection of light will be described below in greater detail.

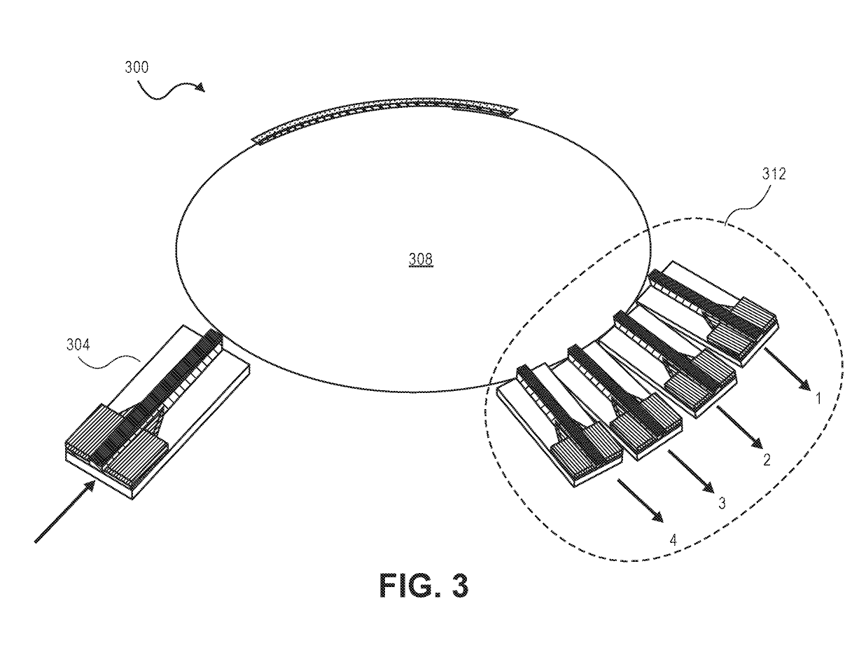

FIG. 3 is a block diagram of an echelle grating (EG)-based wavelength demultiplexer (DEMUX) 300. DEMUX 300 illustrates the square box flat-top working principle that applies equally well to AWG-based devices. In this example, light of multiple wavelengths is received at input waveguide 304. The light then propagates into a silicon slab 308. An EG DEMUX 312 includes the single input waveguide 304, and four output waveguides 312 numbered 1 through 4, respectively. These include highly-reflective grating surfaces. The grating may include a series of linear or curved micromirrors arranged on a curved line, in a manner that provides constructive interference and focusing for the target wavelength at the input entry point along the output waveguide 312. The EG reflects and disperses the different wavelengths and causes them to constructively interfere at different output waveguides numbered 1 through 4.

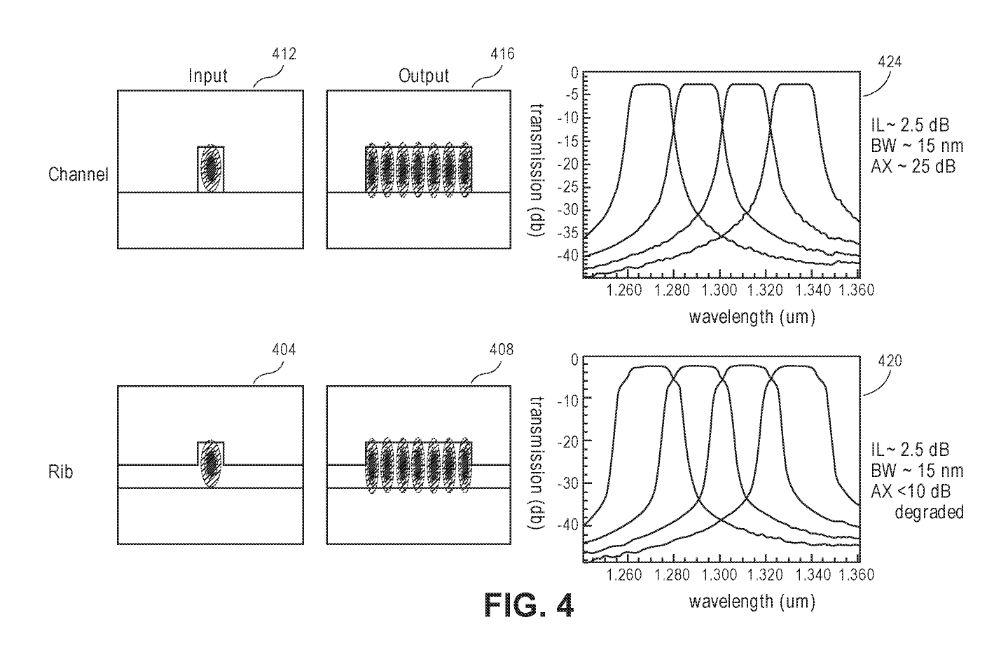

For Si or Si₃N₄ demultiplexers, a typical configuration may include a rib waveguide used as a single-mode input waveguide, where the output waveguides are rib waveguides (e.g., multimode waveguides) to provide a low-loss, flat-top passband in transmission. Alternatively, these may be single-mode waveguides providing a flat-top passband in transmission, but with higher loss. When the rib waveguides are used at the input or output, because of the large mode sizes in the rib waveguides, higher channel isolation may be generated at the output waveguides. To mitigate this limitation, a rib-to-channel converter according to the teachings of the present specification may be implemented. This can enable the channel waveguides to be placed right at the input and output of slab 308. Significant channel isolation reduction and optical crosstalk are shown in the optical simulation of FIG. 4.

FIG. 4 illustrates a waveguide manufactured according to an existing rib technique. This is illustrated in blocks 404 and 408, in which a single mode is shown in the input waveguide, and multiple modes are shown in the output waveguide, respectively. A rib-to-channel converter may be used to manufacture a channel waveguide such as is illustrated in block 412 for a single mode, and in block 416 for a plurality of modes. Graph 420 illustrates crosstalk between the four different wavelengths in the rib waveguide. Graph 424 illustrates crosstalk in the channel waveguides. As evidenced in these graphs, which illustrate simulation results of the channel waveguide of the present specification, graph 424 realizes a square box flat-top isolation pattern between the four wavelength channels. In comparison, the rib waveguide of graph 420 realizes much more substantial crosstalk among four wavelength channels.

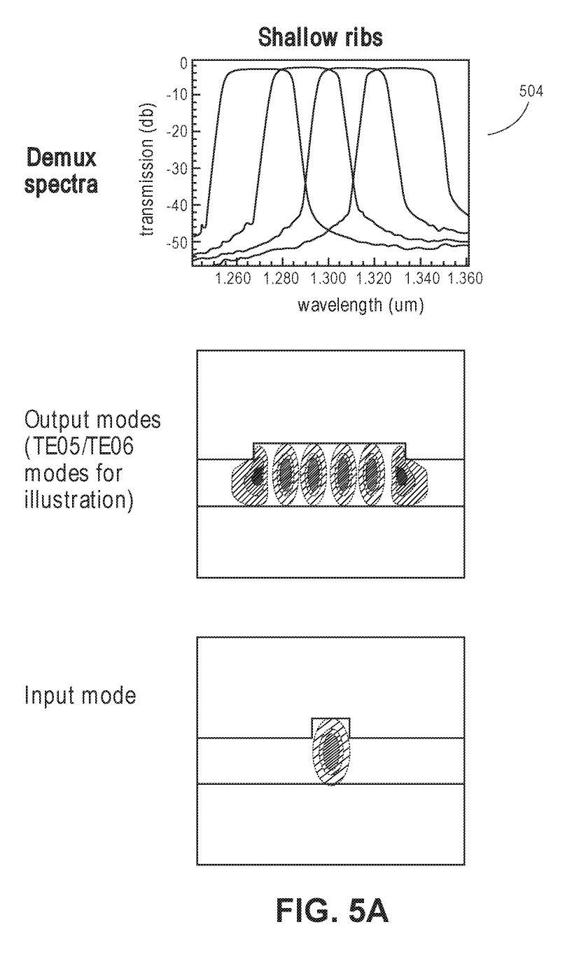

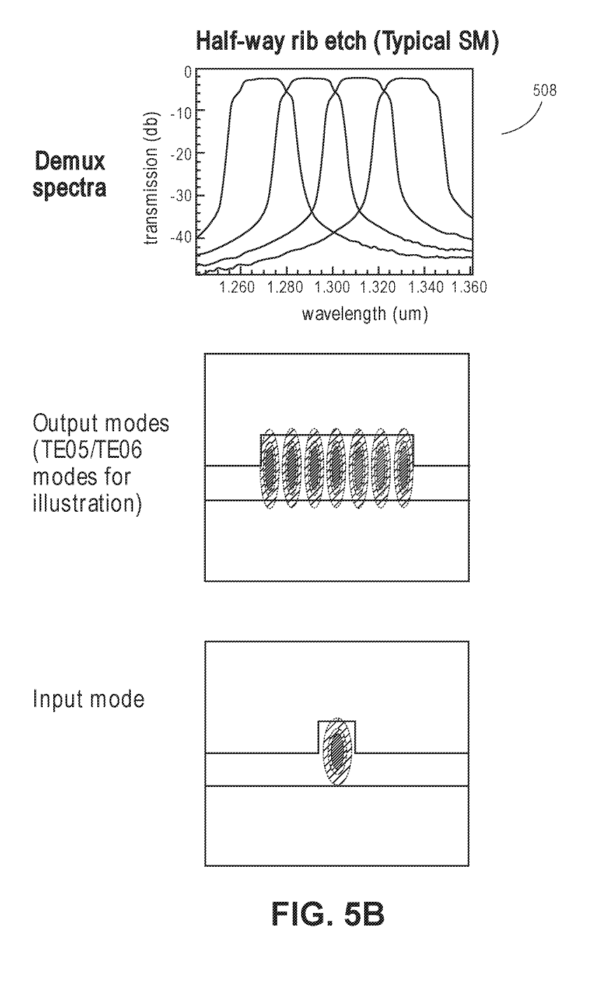

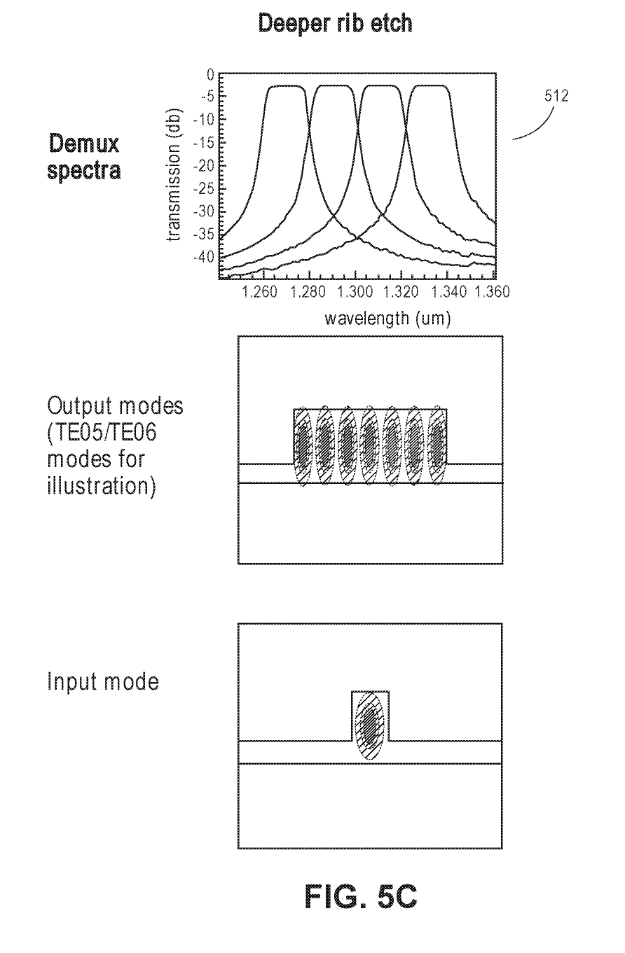

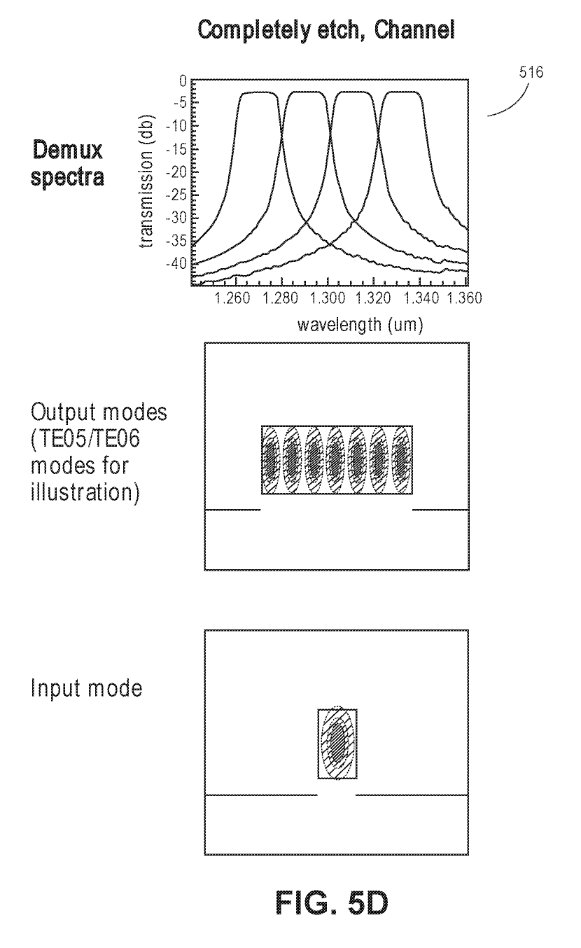

FIGS. 5A-5D illustrate the relationship between rib etch depth and inter-mode isolation. FIG. 5A illustrates shallow ribs, with a graph of DEMUX spectra 504 illustrating substantial crosstalk. FIG. 5B illustrates a half-way rib etch. Graph 508 is an illustration of the DEMUX spectra for this configuration. As shown, the half-way rib etch realizes better inter-mode isolation than the shallow ribs of FIG. 5A. FIG. 5C illustrates a deeper rib etch. Graph 512 illustrates that still better inter-mode isolation is realized by the deeper rib etch.

FIG. 5D illustrates a completely etched channel, according to the teachings of the present specification. As can be seen in graph 516, the completely etched channel realizes superior isolation among all of the rib configurations in FIGS. 5A, 5B, 5C, and 5D.

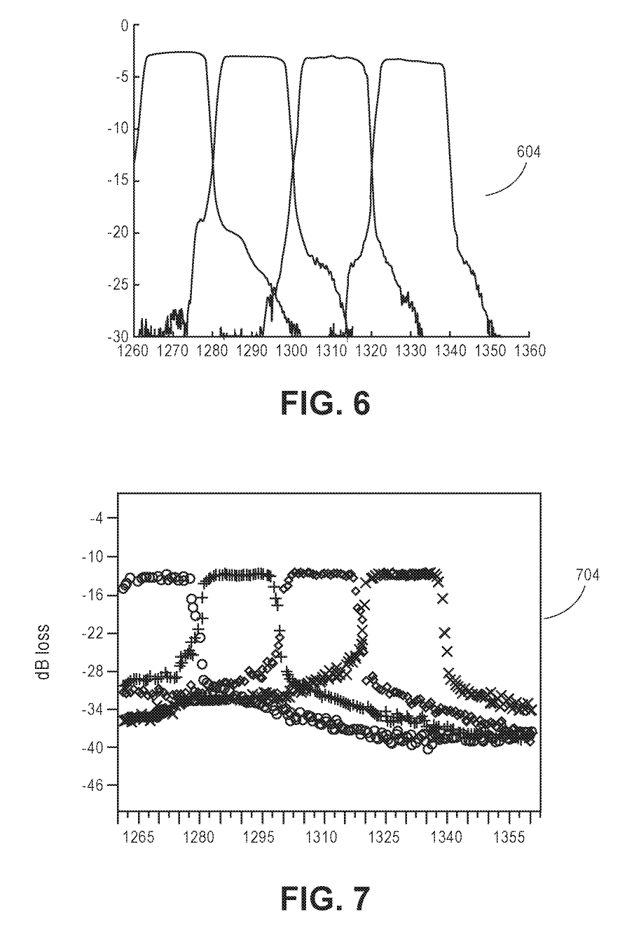

FIGS. 6 and 7 illustrate the realization of experimental results from a completely etched channel waveguide prototype. Graph 604 of FIG. 6 illustrates a square box-like flat-top DEMUX optical-optical (OO) test at the die level. Graph 704 of FIG. 7 illustrates a photocurrent response versus wavelength from an integrated DEMUX and photodetector at wafer-level test. Graph 704 was realized with a single receiver die. Additional tests were performed for a single 300 mm wafer level. Both OO tests in a standalone DEMUX and optical-electrical (OE) tests in a receiver showed the square box-like flat-top spectral response in the receiver. The measured results of the manufactured prototype substantially matched the simulation results.

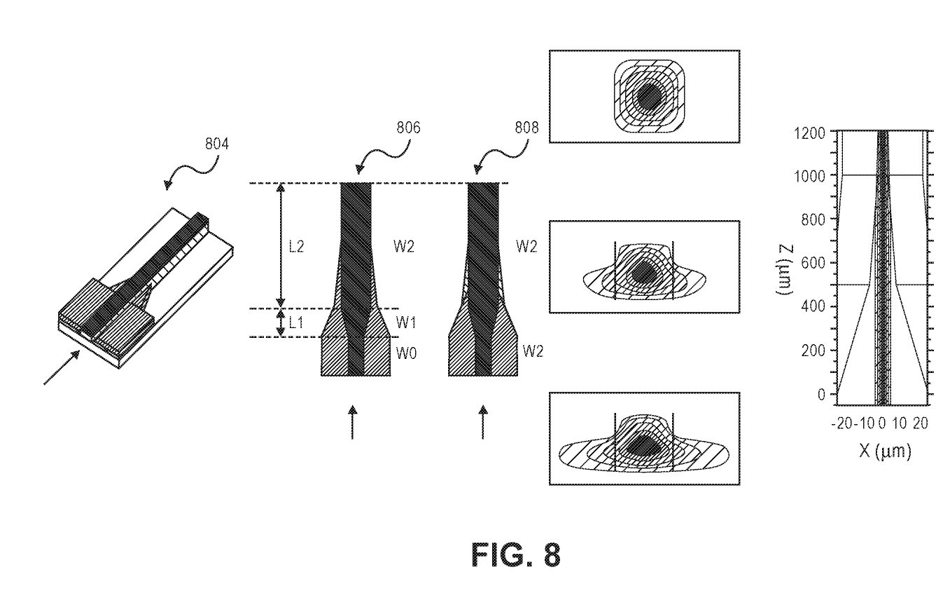

FIG. 8 illustrates selected aspects of a rib-to-channel converter 804. To make the rib-to-channel waveguides transition adiabatically without inducing excess loss, appropriate taper designs may be employed. These may be combined with a double-etching step optimized in different configurations based, for example, on the Si or Si₃N₄ thickness. For example, taper widths and links may be two sessions (W0, W1, and W2, and L1/L2 as illustrated in 806). Alternatively, the taper widths and lengths may have the same width during the double-etching process, as illustrated in 808.

For example, the simulated loss is less than 0.2 dB per single-mode, rib-to-channel transition. The actual measured loss is approximately 0.1 dB per single-mode condition (SMC) by cutback, and approximately 0.2 dB worst-case measured per SMC. Note that the performance of the manufactured prototype matches well with the simulations.

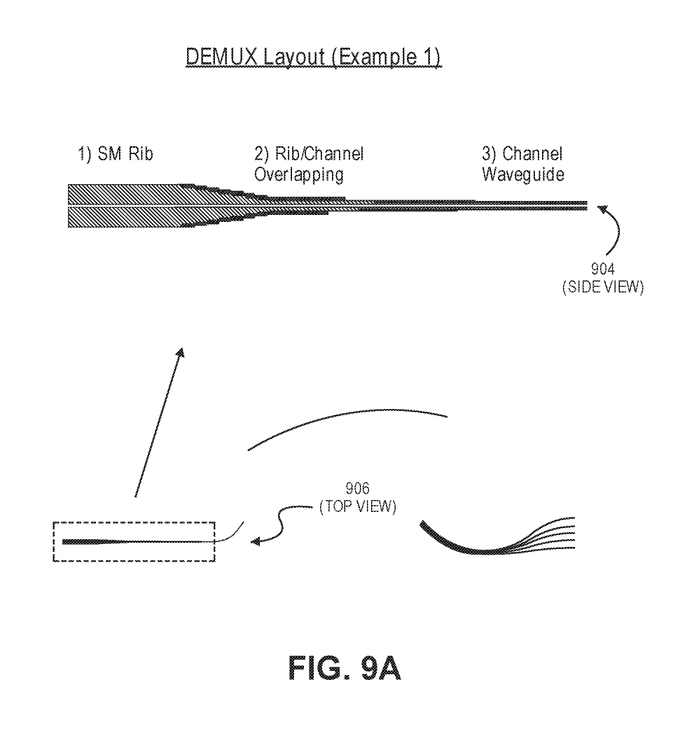

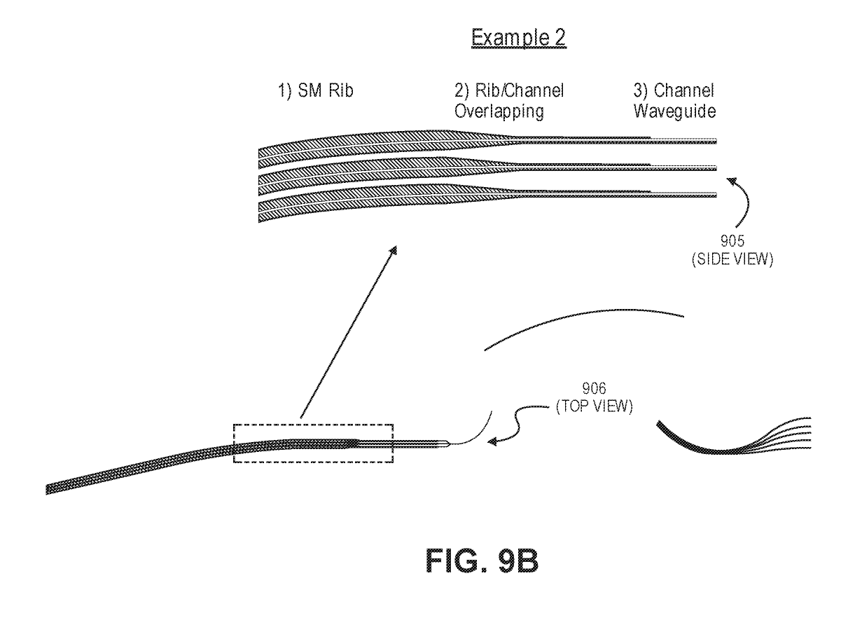

FIGS. 9A and 9B illustrate two examples of a DEMUX layout. In the actual DEMUX designs, the rib-to-channel converter may be implemented in some cases only at the single input of the EG, while the output waveguides may all be channel waveguide connections to the photodetector arrays. This is illustrated in FIG. 9A, Example 1, with a single-mode (SM) rib, a rib-channel overlap, and a channel waveguide. This is shown in both a side view 904 and a top view 906. FIG. 9B provides a second example DEMUX layout. The rib-to-channel converter may be implemented in some cases with multiple inputs of the EG, while the output waveguides may all be channel waveguide connections to the photodetector arrays. Illustrated in FIG. 9B are multiple SM ribs, multiple rib-channel overlaps, and multiple channel waveguides. This is shown in both a side view 904 and a top view 906. In some cases, the rib waveguide can also be designed in the curved routing to interconnect with other devices, as illustrated by the SM rib sections in FIG. 9B.

Other implementations may be applied at both input/output sides, as illustrated in FIG. 3. In some embodiments, the optical device 300 may be formed on a silicon-on-insulator (SOI) platform. Accordingly, the optical device 300 may be formed in a semiconductor layer (e.g., including silicon) 308 or other silicon-based material. For example, in some embodiments, the semiconductor layer 308 may be provided on high index waveguide platforms, such as silicon nitride (Si3N4) waveguide-buried oxide (BOX)-silicon substrate, or silicon oxynitride (SiON) waveguide-BOX-Si substrate.

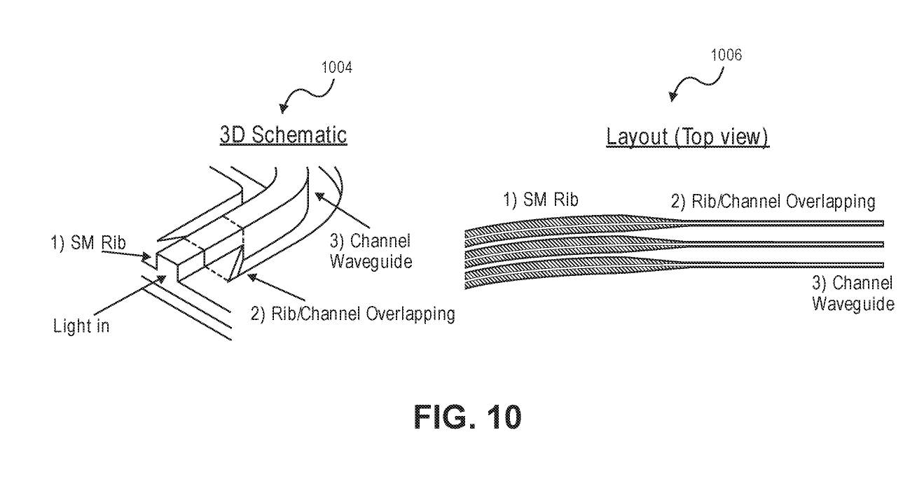

FIG. 10 illustrates additional details of a layout schematic, including a 3D schematic 1004 and a top-view layout 1006. Cross-sectional changes can be seen in FIG. 10 from SM rib 1, to rib-channel overlap region 2, to channel waveguides 3.

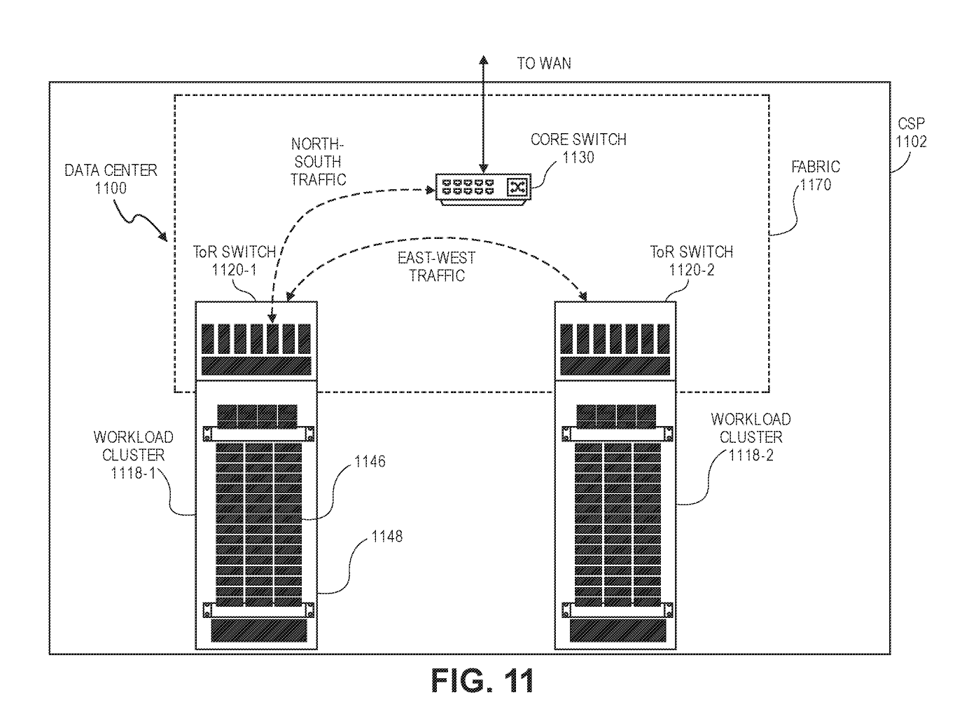

FIG. 11 is a block diagram of selected components of a data center 1100 with network connectivity. Embodiments of data center 1100 disclosed herein may be adapted or configured to provide a wavelength demultiplexer, according to the teachings of the present specification. Data center 1100 is disclosed in this illustration as a data center operated by a CSP 1102, but this is an illustrative example only. The principles illustrated herein may also be applicable to an HPC cluster, a smaller “edge” data center, a microcloud, or other interconnected compute structure.

CSP 1102 may be, by way of nonlimiting example, a traditional enterprise data center, an enterprise “private cloud,” or a “public cloud,” providing services such as infrastructure as a service (IaaS), platform as a service (PaaS), or software as a service (SaaS). In some cases, CSP 1102 may provide, instead of or in addition to cloud services, HPC platforms or services. Indeed, while not expressly identical, HPC clusters (“supercomputers”) may be structurally similar to cloud data centers, and unless expressly specified, the teachings of this specification may be applied to either. In general usage, the “cloud” is considered to be separate from an enterprise data center. Whereas an enterprise data center may be owned and operated on-site by an enterprise, a CSP provides third-party compute services to a plurality of “tenants.” Each tenant may be a separate user or enterprise, and may have its own allocated resources, SLAs, and similar.

CSP 1102 may provision some number of workload clusters 1118, which may be clusters of individual servers, blade servers, rackmount servers, or any other suitable server topology. In this illustrative example, two workload clusters, 1118-1 and 1118-2 are shown, each providing rackmount servers 1146 in a chassis 1148.

In this illustration, workload clusters 1118 are shown as modular workload clusters conforming to the rack unit (“U”) standard, in which a standard rack, 19 inches wide, may accommodate up to 42 units (42 U), each 1.75 inches high and approximately 36 inches deep. In this case, compute resources such as processors, memory, storage, accelerators, and switches may fit into some multiple of rack units from 1 U to 42 U.

In the case of a traditional rack-based data center, each server 1146 may host a standalone operating system and provide a server function, or servers may be virtualized, in which case they may be under the control of a virtual machine manager (VMM), hypervisor, and/or orchestrator. Each server may then host one or more virtual machines, virtual servers, or virtual appliances. These server racks may be collocated in a single data center, or may be located in different geographic data centers. Depending on contractual agreements, some servers 1146 may be specifically dedicated to certain enterprise clients or tenants, while others may be shared.

The various devices in a data center may be connected to each other via a switching fabric 1170, which may include one or more high speed routing and/or switching devices. Switching fabric 1170 may provide both “north-south” traffic (e.g., traffic to and from the wide area network (WAN), such as the Internet), and “east-west” traffic (e.g., traffic across the data center). Historically, north-south traffic accounted for the bulk of network traffic, but as web services become more complex and distributed, the volume of east-west traffic has risen. In many data centers, east-west traffic now accounts for the majority of traffic.

Furthermore, as the capability of each server 1146 increases, traffic volume may further increase. For example, each server 1146 may provide multiple processor slots, with each slot accommodating a processor having four to eight cores, along with sufficient memory for the cores. Thus, each server may host a number of virtual machines (VMs), each generating its own traffic.

To accommodate the large volume of traffic in a data center, a highly capable switching fabric 1170 may be provided. As used throughout this specification, a “fabric” should be broadly understood to include any combination of physical interconnects, protocols, media, and support resources that provide communication between one or more first discrete devices and one or more second discrete devices. Fabrics may be one-to-one, one-to-many, many-to-one, or many-to-many.

In some embodiments, fabric 1170 may provide communication services on various “layers,” as outlined in the Open Systems Interconnection (OSI) seven-layer network model. In contemporary practice, the OSI model is not followed strictly. In general terms, layers 1 and 2 are often called the “Ethernet” layer (though in some data centers or supercomputers, Ethernet may be supplanted or supplemented by newer technologies). Layers 3 and 4 are often referred to as the transmission control protocol/internet protocol (TCP/IP) layer (which may be further subdivided into TCP and IP layers). Layers 5-7 may be referred to as the “application layer.” These layer definitions are disclosed as a useful framework, but are intended to be nonlimiting.

Switching fabric 1170 is illustrated in this example as a “flat” network, wherein each server 1146 may have a direct connection to a top-of-rack (ToR) switch 1120 (e.g., a “star” configuration). Note that ToR is a common and historical name, and ToR switch 1120 may, in fact, be located anywhere on the rack. Some data centers place ToR switch 1120 in the middle of the rack to reduce the average overall cable length.

Each ToR switch 1120 may couple to a core switch 1130. This two-tier flat network architecture is shown only as an illustrative example. In other examples, other architectures may be used, such as three-tier star or leaf-spine (also called “fat tree” topologies) based on the “Clos” architecture, hub-and-spoke topologies, mesh topologies, ring topologies, or 3-D mesh topologies, by way of nonlimiting example.

The fabric itself may be provided by any suitable interconnect. For example, each server 1146 may include an Intel® Host Fabric Interface (HFI), a network interface card (NIC), intelligent NIC (iNIC), smart NIC, a host channel adapter (HCA), or other host interface. For simplicity and unity, these may be referred to throughout this specification as a “fabric adapter” (FA), which should be broadly construed as an interface to communicatively couple the host to the data center fabric. The FA may couple to one or more host processors via an interconnect or bus, such as PCI, PCIe, or similar, referred to herein as a “local fabric.” Multiple processor may communicate with one another via a special interconnects such as a core-to-core Ultra Path Interconnect (UPI), Infinity Fabric, etc. Generically, these interconnects may be referred to as an “inter-processor fabric.” The treatment of these various fabrics may vary from vendor to vendor and from architecture to architecture. In some cases, one or both of the local fabric and the inter-processor fabric may be treated as part of the larger data center fabric 1172. Some FAs have the capability to dynamically handle a physical connection with a plurality of protocols (e.g., either Ethernet or PCIe, depending on the context), in which case PCIe connections to other parts of a rack may usefully be treated as part of fabric 1172. In other embodiments, PCIe is used exclusively within a local node, sled, or sled chassis, in which case it may not be logical to treat the local fabric as part of data center fabric 1172. In yet other embodiments, it is more logically to treat the inter-processor fabric as part of the secure domain of the processor complex, and thus treat it separately from the local fabric and/or data center fabric 1172. In particular, the inter-processor fabric may be cache and/or memory-coherent, meaning that coherent devices can map to the same memory address space, with each treating that address space as its own local address space. Many data center fabrics and local fabrics lack coherency, and so it may be beneficial to treat inter-processor fabric, the local fabric, and the data center fabric as one cohesive fabric, or two or three separate fabrics. Furthermore, the illustration of three levels of fabric in this example should not be construed to exclude more or fewer levels of fabrics, or the mixture of other kinds of fabrics. For example, many data centers use copper interconnects for short communication distances, and fiberoptic interconnects for longer distances.

Thus, fabric 1170 may be provided by a single interconnect or a hybrid interconnect, such as where PCIe provides on-chip (for a system-on-a-chip) or on-board communication, 1 Gb or 10 Gb copper Ethernet provides relatively short connections to a ToR switch 1120, and optical cabling provides relatively longer connections to core switch 1130. Interconnect technologies that may be found in the data center include, by way of nonlimiting example, Intel® silicon photonics, an Intel® HFI, a NIC, intelligent NIC (iNIC), smart NIC, an HCA or other host interface, PCI, PCIe, a core-to-core UPI (formerly called QPI or KTI), Infinity Fabric, Intel® Omni-Path™ Architecture (OPA), TrueScale™, FibreChannel, Ethernet, FibreChannel over Ethernet (FCoE), InfiniBand, a legacy interconnect such as a local area network (LAN), a token ring network, a synchronous optical network (SONET), an asynchronous transfer mode (ATM) network, a wireless network such as Wi-Fi or Bluetooth, a “plain old telephone system” (POTS) interconnect or similar, a multi-drop bus, a mesh interconnect, a point-to-point interconnect, a serial interconnect, a parallel bus, a coherent (e.g., cache coherent) bus, a layered protocol architecture, a differential bus, or a Gunning transceiver logic (GTL) bus, to name just a few. The fabric may be cache- and memory-coherent, cache- and memory-non-coherent, or a hybrid of coherent and non-coherent interconnects. Some interconnects are more popular for certain purposes or functions than others, and selecting an appropriate fabric for the instant application is an exercise of ordinary skill. For example, OPA and lnfiniband are commonly used in HPC applications, while Ethernet and FibreChannel are more popular in cloud data centers. But these examples are expressly nonlimiting, and as data centers evolve fabric technologies similarly evolve.

Note that while high-end fabrics such as OPA are provided herein by way of illustration, more generally, fabric 1170 may be any suitable interconnect or bus for the particular application. This could, in some cases, include legacy interconnects like LANs, token ring networks, synchronous optical networks (SONET), ATM networks, wireless networks such as Wi-Fi and Bluetooth, POTS interconnects, or similar. It is also expressly anticipated that in the future, new network technologies may arise to supplement or replace some of those listed here, and any such future network topologies and technologies can be or form a part of fabric 1170.

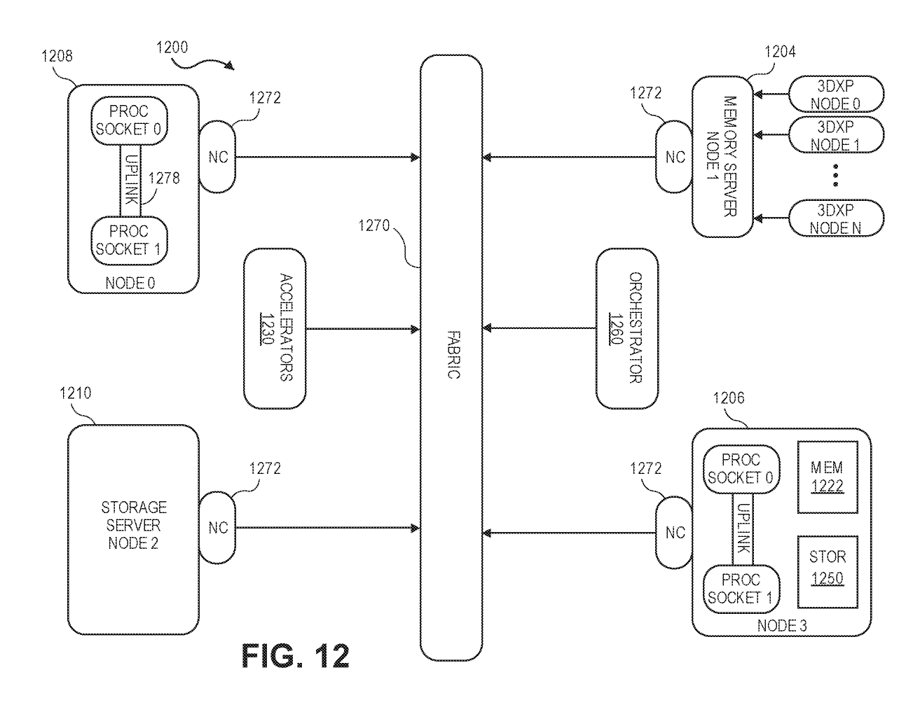

FIG. 12 is a block diagram of an end-user computing device 1200. Embodiments of computing device 1200 disclosed herein may be adapted or configured to provide a wavelength demultiplexer, according to the teachings of the present specification. As above, computing device 1200 may provide, as appropriate, cloud service, HPC, telecommunication services, enterprise data center services, or any other compute services that benefit from a computing device 1200.

In this example, a fabric 1270 is provided to interconnect various aspects of computing device 1200. Fabric 1270 may be the same as fabric 1170 of FIG. 11, or may be a different fabric. As above, fabric 1270 may be provided by any suitable interconnect technology. In this example, Intel® Omni-Path™ is used as an illustrative and nonlimiting example.

As illustrated, computing device 1200 includes a number of logic elements forming a plurality of nodes. It should be understood that each node may be provided by a physical server, a group of servers, or other hardware. Each server may be running one or more virtual machines as appropriate to its application.

Node 0 1208 is a processing node including a processor socket 0 and processor socket 1. The processors may be, for example, Intel® Xeon™ processors with a plurality of cores, such as 4 or 8 cores. Node 0 1208 may be configured to provide network or workload functions, such as by hosting a plurality of virtual machines or virtual appliances.

On-board communication between processor socket 0 and processor socket 1 may be provided by an on-board uplink 1278. This may provide a very high speed, short-length interconnect between the two processor sockets, so that virtual machines running on node 0 1208 can communicate with one another at very high speeds. To facilitate this communication, a virtual switch (vSwitch) may be provisioned on node 0 1208, which may be considered to be part of fabric 1270.

Node 0 1208 connects to fabric 1270 via a network controller (NC) 1272. NC 1272 provides physical interface (a PHY level) and logic to communicatively couple a device to a fabric. For example, NC 1272 may be a NIC to communicatively couple to an Ethernet fabric or an HFI to communicatively couple to a clustering fabric such as an Intel° Omni-Path™, by way of illustrative and nonlimiting example. In some examples, communication with fabric 1270 may be tunneled, such as by providing UPI tunneling over Omni-Path™.

Because computing device 1200 may provide many functions in a distributed fashion that in previous generations were provided on-board, a highly capable NC 1272 may be provided. NC 1272 may operate at speeds of multiple gigabits per second, and in some cases may be tightly coupled with node 0 1208. For example, in some embodiments, the logic for NC 1272 is integrated directly with the processors on a system-on-a-chip (SoC). This provides very high speed communication between NC 1272 and the processor sockets, without the need for intermediary bus devices, which may introduce additional latency into the fabric. However, this is not to imply that embodiments where NC 1272 is provided over a traditional bus are to be excluded. Rather, it is expressly anticipated that in some examples, NC 1272 may be provided on a bus, such as a PCIe bus, which is a serialized version of PCI that provides higher speeds than traditional PCI. Throughout computing device 1200, various nodes may provide different types of NCs 1272, such as on-board NCs and plug-in NCs. It should also be noted that certain blocks in an SoC may be provided as IP blocks that can be “dropped” into an integrated circuit as a modular unit. Thus, NC 1272 may in some cases be derived from such an IP block.

Note that in “the network is the device” fashion, node 0 1208 may provide limited or no on-board memory or storage. Rather, node 0 1208 may rely primarily on distributed services, such as a memory server and a networked storage server. On-board, node 0 1208 may provide only sufficient memory and storage to bootstrap the device and get it communicating with fabric 1270. This kind of distributed architecture is possible because of the very high speeds of contemporary data centers, and may be advantageous because there is no need to over-provision resources for each node. Rather, a large pool of high speed or specialized memory may be dynamically provisioned between a number of nodes, so that each node has access to a large pool of resources, but those resources do not sit idle when that particular node does not need them.

In this example, a node 1 memory server 1204 and a node 2 storage server 1210 provide the operational memory and storage capabilities of node 0 1208. For example, memory server node 1 1204 may provide remote direct memory access (RDMA), whereby node 0 1208 may access memory resources on node 1 1204 via fabric 1270 in a direct memory access fashion, similar to how it would access its own on-board memory. The memory provided by memory server 1204 may be traditional memory, such as double data rate type 3 (DDR3) dynamic random access memory (DRAM), which is volatile, or may be a more exotic type of memory, such as a persistent fast memory (PFM) like Intel® 3D Crosspoint™ (3DXP), which operates at DRAM-like speeds, but is non-volatile.

Similarly, rather than providing an on-board hard disk for node 0 1208, a storage server node 2 1210 may be provided. Storage server 1210 may provide a networked bunch of disks (NBOD), PFM, redundant array of independent disks (RAID), redundant array of independent nodes (RAIN), network-attached storage (NAS), optical storage, tape drives, or other non-volatile memory solutions.

Thus, in performing its designated function, node 0 1208 may access memory from memory server 1204 and store results on storage provided by storage server 1210. Each of these devices couples to fabric 1270 via an NC 1272, which provides fast communication that makes these technologies possible.

By way of further illustration, node 3 1206 is also depicted. Node 3 1206 also includes an NC 1272, along with two processor sockets internally connected by an uplink. However, unlike node 0 1208, node 3 1206 includes its own on-board memory 1222 and storage 1250. Thus, node 3 1206 may be configured to perform its functions primarily on-board, and may not be required to rely upon memory server 1204 and storage server 1210. However, in appropriate circumstances, node 3 1206 may supplement its own on-board memory 1222 and storage 1250 with distributed resources similar to node 0 1208.

Computing device 1200 may also include accelerators 1230. These may provide various accelerated functions, including hardware or co-processor acceleration for functions such as packet processing, encryption, decryption, compression, decompression, network security, or other accelerated functions in the data center. In some examples, accelerators 1230 may include deep learning accelerators that may be directly attached to one or more cores in nodes such as node 0 1208 or node 3 1206. Examples of such accelerators can include, by way of nonlimiting example, Intel® QuickData Technology (QDT), Intel® QuickAssist Technology (11T), Intel® Direct Cache Access (DCA), Intel® Extended Message Signaled Interrupt (MSI-X), Intel® Receive Side Coalescing (RSC), and other acceleration technologies.

In other embodiments, an accelerator could also be provided as an application-specific integrated circuit (ASIC), field-programmable gate array (FPGA), co-processor, graphics processing unit (GPU), digital signal processor (DSP), or other processing entity, which may optionally be tuned or configured to provide the accelerator function.

The basic building block of the various components disclosed herein may be referred to as “logic elements.” Logic elements may include hardware (including, for example, a software-programmable processor, an ASIC, or an FPGA), external hardware (digital, analog, or mixed-signal), software, reciprocating software, services, drivers, interfaces, components, modules, algorithms, sensors, components, firmware, microcode, programmable logic, or objects that can coordinate to achieve a logical operation. Furthermore, some logic elements are provided by a tangible, non-transitory computer-readable medium having stored thereon executable instructions for instructing a processor to perform a certain task. Such a non-transitory medium could include, for example, a hard disk, solid state memory or disk, read-only memory (ROM), PFM (e.g., Intel® 3D Crosspoint™), external storage, RAID, RAIN, NAS, optical storage, tape drive, backup system, cloud storage, or any combination of the foregoing by way of nonlimiting example. Such a medium could also include instructions programmed into an FPGA, or encoded in hardware on an ASIC or processor.

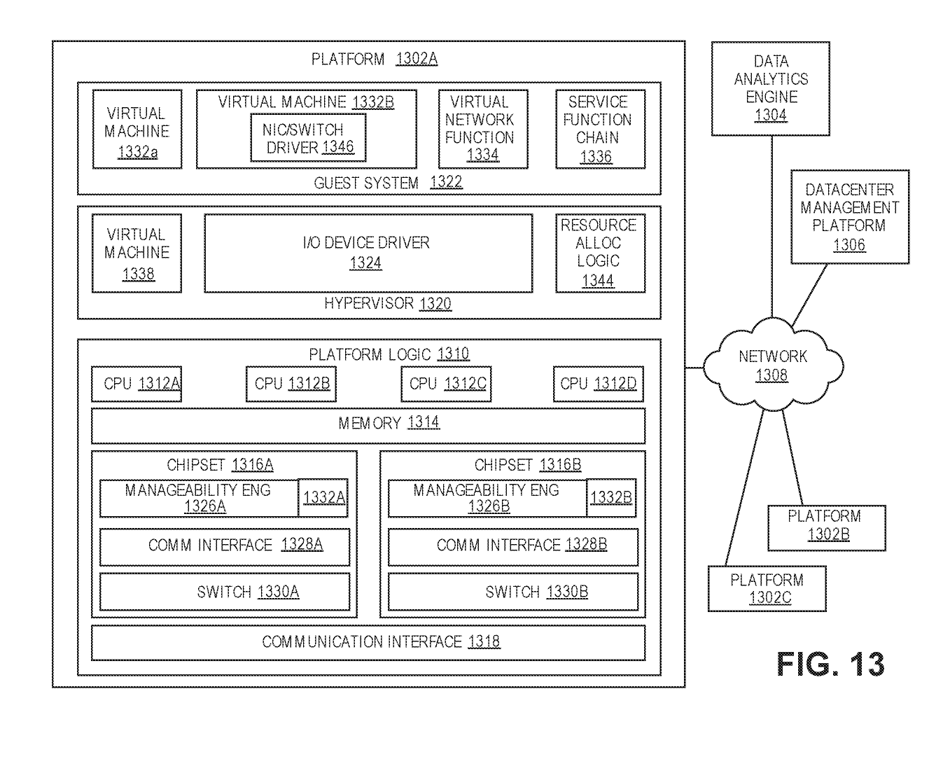

FIG. 13 is a block diagram of components of a computing platform 1302A. Embodiments of computing platform 1302A disclosed herein may be adapted or configured to provide a wavelength demultiplexer, according to the teachings of the present specification.

In the embodiment depicted, hardware platforms 1302A, 1302B, and 1302C, along with a data center management platform 1306 and data analytics engine 1304 are interconnected via network 1308. In other embodiments, a computer system may include any suitable number of (i.e., one or more) platforms, including hardware, software, firmware, and other components. In some embodiments (e.g., when a computer system only includes a single platform), all or a portion of the system management platform 1306 may be included on a platform 1302. A platform 1302 may include platform logic 1310 with one or more central processing units (CPUs) 1312, memories 1314 (which may include any number of different modules), chipsets 1316, communication interfaces 1318, and any other suitable hardware and/or software to execute a hypervisor 1320 or other operating system capable of executing workloads associated with applications running on platform 1302. In some embodiments, a platform 1302 may function as a host platform for one or more guest systems 1322 that invoke these applications. Platform 1302A may represent any suitable computing environment, such as a high-performance computing environment, a data center, a communications service provider infrastructure (e.g., one or more portions of an Evolved Packet Core), an in-memory computing environment, a computing system of a vehicle (e.g., an automobile or airplane), an Internet of Things environment, an industrial control system, other computing environment, or combination thereof.

In various embodiments of the present disclosure, accumulated stress and/or rates of stress accumulated of a plurality of hardware resources (e.g., cores and uncores) are monitored and entities (e.g., system management platform 1306, hypervisor 1320, or other operating system) of computer platform 1302A may assign hardware resources of platform logic 1310 to perform workloads in accordance with the stress information. In some embodiments, self-diagnostic capabilities may be combined with the stress monitoring to more accurately determine the health of the hardware resources. Each platform 1302 may include platform logic 1310. Platform logic 1310 comprises, among other logic enabling the functionality of platform 1302, one or more CPUs 1312, memory 1314, one or more chipsets 1316, and communication interfaces 1328. Although three platforms are illustrated, computer platform 1302A may be interconnected with any suitable number of platforms. In various embodiments, a platform 1302 may reside on a circuit board that is installed in a chassis, rack, or other suitable structure that comprises multiple platforms coupled together through network 1308 (which may comprise, e.g., a rack or backplane switch).

CPUs 1312 may each comprise any suitable number of processor cores and supporting logic (e.g., uncores). The cores may be coupled to each other, to memory 1314, to at least one chipset 1316, and/or to a communication interface 1318, through one or more controllers residing on CPU 1312 and/or chipset 1316. In particular embodiments, a CPU 1312 is embodied within a socket that is permanently or removably coupled to platform 1302A. Although four CPUs are shown, a platform 1302 may include any suitable number of CPUs.

Memory 1314 may comprise any form of volatile or non-volatile memory including, without limitation, magnetic media (e.g., one or more tape drives), optical media, random access memory (RAM), ROM, flash memory, removable media, or any other suitable local or remote memory component or components. Memory 1314 may be used for short, medium, and/or long-term storage by platform 1302A. Memory 1314 may store any suitable data or information utilized by platform logic 1310, including software embedded in a computer-readable medium, and/or encoded logic incorporated in hardware or otherwise stored (e.g., firmware). Memory 1314 may store data that is used by cores of CPUs 1312. In some embodiments, memory 1314 may also comprise storage for instructions that may be executed by the cores of CPUs 1312 or other processing elements (e.g., logic resident on chipsets 1316) to provide functionality associated with the manageability engine 1326 or other components of platform logic 1310. A platform 1302 may also include one or more chipsets 1316 comprising any suitable logic to support the operation of the CPUs 1312. In various embodiments, chipset 1316 may reside on the same die or package as a CPU 1312 or on one or more different dies or packages. Each chipset may support any suitable number of CPUs 1312. A chipset 1316 may also include one or more controllers to couple other components of platform logic 1310 (e.g., communication interface 1318 or memory 1314) to one or more CPUs. In the embodiment depicted, each chipset 1316 also includes a manageability engine 1326. Manageability engine 1326 may include any suitable logic to support the operation of chipset 1316. In a particular embodiment, a manageability engine 1326 (which may also be referred to as an innovation engine) is capable of collecting real-time telemetry data from the chipset 1316, the CPU(s) 1312 and/or memory 1314 managed by the chipset 1316, other components of platform logic 1310, and/or various connections between components of platform logic 1310. In various embodiments, the telemetry data collected includes the stress information described herein.

In various embodiments, a manageability engine 1326 operates as an out-of-band asynchronous compute agent which is capable of interfacing with the various elements of platform logic 1310 to collect telemetry data with no or minimal disruption to running processes on CPUs 1312. For example, manageability engine 1326 may comprise a dedicated processing element (e.g., a processor, controller, or other logic) on chipset 1316, which provides the functionality of manageability engine 1326 (e.g., by executing software instructions), thus conserving processing cycles of CPUs 1312 for operations associated with the workloads performed by the platform logic 1310. Moreover the dedicated logic for the manageability engine 1326 may operate asynchronously with respect to the CPUs 1312 and may gather at least some of the telemetry data without increasing the load on the CPUs.

A manageability engine 1326 may process telemetry data it collects (specific examples of the processing of stress information are provided herein). In various embodiments, manageability engine 1326 reports the data it collects and/or the results of its processing to other elements in the computer system, such as one or more hypervisors 1320 or other operating systems and/or system management software (which may run on any suitable logic such as system management platform 1306). In particular embodiments, a critical event such as a core that has accumulated an excessive amount of stress may be reported prior to the normal interval for reporting telemetry data (e.g., a notification may be sent immediately upon detection).

Additionally, manageability engine 1326 may include programmable code configurable to set which CPU(s) 1312 a particular chipset 1316 manages and/or which telemetry data may be collected.

Chipsets 1316 also each include a communication interface 1328. Communication interface 1328 may be used for the communication of signaling and/or data between chipset 1316 and one or more I/O devices, one or more networks 1308, and/or one or more devices coupled to network 1308 (e.g., system management platform 1306). For example, communication interface 1328 may be used to send and receive network traffic such as data packets. In a particular embodiment, a communication interface 1328 comprises one or more physical network interface controllers (NICs), also known as network interface cards or network adapters. A NIC may include electronic circuitry to communicate using any suitable physical layer and data link layer standard such as Ethernet (e.g., as defined by a IEEE 802.3 standard), Fibre Channel, InfiniBand, Wi-Fi, or other suitable standard. A NIC may include one or more physical ports that may couple to a cable (e.g., an Ethernet cable). A NIC may enable communication between any suitable element of chipset 1316 (e.g., manageability engine 1326 or switch 1330) and another device coupled to network 1308. In various embodiments a NIC may be integrated with the chipset (i.e., may be on the same integrated circuit or circuit board as the rest of the chipset logic) or may be on a different integrated circuit or circuit board that is electromechanically coupled to the chipset.

In particular embodiments, communication interfaces 1328 may allow communication of data (e.g., between the manageability engine 1326 and the data center management platform 1306) associated with management and monitoring functions performed by manageability engine 1326. In various embodiments, manageability engine 1326 may utilize elements (e.g., one or more NICs) of communication interfaces 1328 to report the telemetry data (e.g., to system management platform 1306) in order to reserve usage of NICs of communication interface 1318 for operations associated with workloads performed by platform logic 1310.

Switches 1330 may couple to various ports (e.g., provided by NICs) of communication interface 1328 and may switch data between these ports and various components of chipset 1316 (e.g., one or more Peripheral Component Interconnect Express (PCIe) lanes coupled to CPUs 1312). Switches 1330 may be a physical or virtual (i.e., software) switch.

Platform logic 1310 may include an additional communication interface 1318. Similar to communication interfaces 1328, communication interfaces 1318 may be used for the communication of signaling and/or data between platform logic 1310 and one or more networks 1308 and one or more devices coupled to the network 1308. For example, communication interface 1318 may be used to send and receive network traffic such as data packets. In a particular embodiment, communication interfaces 1318 comprise one or more physical NICs. These NICs may enable communication between any suitable element of platform logic 1310 (e.g., CPUs 1312 or memory 1314) and another device coupled to network 1308 (e.g., elements of other platforms or remote computing devices coupled to network 1308 through one or more networks).

Platform logic 1310 may receive and perform any suitable types of workloads. A workload may include any request to utilize one or more resources of platform logic 1310, such as one or more cores or associated logic. For example, a workload may comprise a request to instantiate a software component, such as an I/O device driver 1324 or guest system 1322; a request to process a network packet received from a virtual machine 1332 or device external to platform 1302A (such as a network node coupled to network 1308); a request to execute a process or thread associated with a guest system 1322, an application running on platform 1302A, a hypervisor 1320 or other operating system running on platform 1302A; or other suitable processing request.

A virtual machine 1332 may emulate a computer system with its own dedicated hardware. A virtual machine 1332 may run a guest operating system on top of the hypervisor 1320. The components of platform logic 1310 (e.g., CPUs 1312, memory 1314, chipset 1316, and communication interface 1318) may be virtualized such that it appears to the guest operating system that the virtual machine 1332 has its own dedicated components.

A virtual machine 1332 may include a virtualized NIC (vNIC), which is used by the virtual machine as its network interface. A vNIC may be assigned a media access control (MAC) address or other identifier, thus allowing multiple virtual machines 1332 to be individually addressable in a network.

VNF 1334 may comprise a software implementation of a functional building block with defined interfaces and behavior that can be deployed in a virtualized infrastructure. In particular embodiments, a VNF 1334 may include one or more virtual machines 1332 that collectively provide specific functionalities (e.g., WAN optimization, virtual private network (VPN) termination, firewall operations, load balancing operations, security functions, etcetera). A VNF 1334 running on platform logic 1310 may provide the same functionality as traditional network components implemented through dedicated hardware. For example, a VNF 1334 may include components to perform any suitable NFV workloads, such as virtualized evolved packet core (vEPC) components, mobility management entities, 3rd Generation Partnership Project (3GPP) control and data plane components, etc.

SFC 1336 is a group of VNFs 1334 organized as a chain to perform a series of operations, such as network packet processing operations. Service function chaining may provide the ability to define an ordered list of network services (e.g. firewalls, load balancers) that are stitched together in the network to create a service chain.

A hypervisor 1320 (also known as a virtual machine monitor) may comprise logic to create and run guest systems 1322. The hypervisor 1320 may present guest operating systems run by virtual machines with a virtual operating platform (i.e., it appears to the virtual machines that they are running on separate physical nodes when they are actually consolidated onto a single hardware platform) and manage the execution of the guest operating systems by platform logic 1310. Services of hypervisor 1320 may be provided by virtualizing in software or through hardware assisted resources that require minimal software intervention, or both. Multiple instances of a variety of guest operating systems may be managed by the hypervisor 1320. Each platform 1302 may have a separate instantiation of a hypervisor 1320.

Hypervisor 1320 may be a native or bare metal hypervisor that runs directly on platform logic 1310 to control the platform logic and manage the guest operating systems. Alternatively, hypervisor 1320 may be a hosted hypervisor that runs on a host operating system and abstracts the guest operating systems from the host operating system. Hypervisor 1320 may include a virtual switch 1338 that may provide virtual switching and/or routing functions to virtual machines of guest systems 1322. The virtual switch 1338 may comprise a logical switching fabric that couples the vNICs of the virtual machines 1332 to each other, thus creating a virtual network through which virtual machines may communicate with each other.

Virtual switch 1338 may comprise a software element that is executed using components of platform logic 1310. In various embodiments, hypervisor 1320 may be in communication with any suitable entity (e.g., a SDN controller) which may cause hypervisor 1320 to reconfigure the parameters of virtual switch 1338 in response to changing conditions in platform 1302 (e.g., the addition or deletion of virtual machines 1332 or identification of optimizations that may be made to enhance performance of the platform).

Hypervisor 1320 may also include resource allocation logic 1344, which may include logic for determining allocation of platform resources based on the telemetry data (which may include stress information). Resource allocation logic 1344 may also include logic for communicating with various components of platform logic 1310 entities of platform 1302A to implement such optimization, such as components of platform logic 1310.

Any suitable logic may make one or more of these optimization decisions. For example, system management platform 1306; resource allocation logic 1344 of hypervisor 1320 or other operating system; or other logic of computer platform 1302A may be capable of making such decisions. In various embodiments, the system management platform 1306 may receive telemetry data from and manage workload placement across multiple platforms 1302. The system management platform 1306 may communicate with hypervisors 1320 (e.g., in an out-of-band manner) or other operating systems of the various platforms 1302 to implement workload placements directed by the system management platform.

The elements of platform logic 1310 may be coupled together in any suitable manner. For example, a bus may couple any of the components together. A bus may include any known interconnect, such as a multi-drop bus, a mesh interconnect, a ring interconnect, a point-to-point interconnect, a serial interconnect, a parallel bus, a coherent (e.g. cache coherent) bus, a layered protocol architecture, a differential bus, or a Gunning transceiver logic (GTL) bus.

Elements of the computer platform 1302A may be coupled together in any suitable manner such as through one or more networks 1308. A network 1308 may be any suitable network or combination of one or more networks operating using one or more suitable networking protocols. A network may represent a series of nodes, points, and interconnected communication paths for receiving and transmitting packets of information that propagate through a communication system. For example, a network may include one or more firewalls, routers, switches, security appliances, antivirus servers, or other useful network devices.

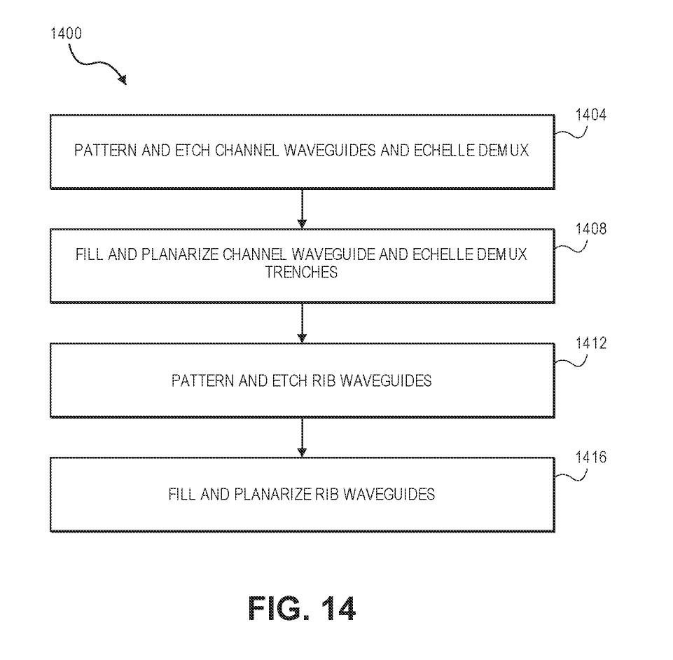

FIG. 14 is a flowchart of an etching process 1400. To fabricate the devices illustrated herein, an integrative, low-cost process is used. The fabrication for waveguides, channel waveguides, and integration processes is compatible with CMOS processes that are used to make other devices and photonic integrated circuits (ICs).

In block 1404, the rib-to-channel converter is fabricated by first etching channel waveguides into the silicon, landing on BOX, which is the buried oxide (BOX) layer in the silicon-on-insulator (SOI) wafers. In block 1408, the channel is filled with a cladding film and the surface is planarized. This planarizes both the channel waveguide and the echelle DEMUX trenches.

In block 1412, the rib waveguides are patterned and etched into the silicon along the channel trenches. In block 1416, the rib waveguide trenches are then filled with a cladding film utilizing a high aspect ratio deposition process. These are then planarized. This provides the rib-to-channel converter as illustrated, for example, in FIG. 9A with the SM rib, the rib-channel overlapped region, and the channel waveguide.

The foregoing outlines features of one or more embodiments of the subject matter disclosed herein. These embodiments are provided to enable a person having ordinary skill in the art (PHOSITA) to better understand various aspects of the present disclosure. Certain well-understood terms, as well as underlying technologies and/or standards may be referenced without being described in detail. It is anticipated that the PHOSITA will possess or have access to background knowledge or information in those technologies and standards sufficient to practice the teachings of the present specification.

The PHOSITA will appreciate that they may readily use the present disclosure as a basis for designing or modifying other processes, structures, or variations for carrying out the same purposes and/or achieving the same advantages of the embodiments introduced herein. The PHOSITA will also recognize that such equivalent constructions do not depart from the spirit and scope of the present disclosure, and that they may make various changes, substitutions, and alterations herein without departing from the spirit and scope of the present disclosure.

In the foregoing description, certain aspects of some or all embodiments are described in greater detail than is strictly necessary for practicing the appended claims. These details are provided by way of nonlimiting example only, for the purpose of providing context and illustration of the disclosed embodiments. Such details should not be understood to be required, and should not be “read into” the claims as limitations. The phrase may refer to “an embodiment” or “embodiments.” These phrases, and any other references to embodiments, should be understood broadly to refer to any combination of one or more embodiments. Furthermore, the several features disclosed in a particular “embodiment” could just as well be spread across multiple embodiments. For example, if features 1 and 2 are disclosed in “an embodiment,” embodiment A may have feature 1 but lack feature 2, while embodiment B may have feature 2 but lack feature 1.

This specification may provide illustrations in a block diagram format, wherein certain features are disclosed in separate blocks. These should be understood broadly to disclose how various features interoperate, but are not intended to imply that those features must necessarily be embodied in separate hardware or software. Furthermore, where a single block discloses more than one feature in the same block, those features need not necessarily be embodied in the same hardware and/or software. For example, a computer “memory” could in some circumstances be distributed or mapped between multiple levels of cache or local memory, main memory, battery-backed volatile memory, and various forms of persistent memory such as a hard disk, storage server, optical disk, tape drive, or similar. In certain embodiments, some of the components may be omitted or consolidated. In a general sense, the arrangements depicted in the figures may be more logical in their representations, whereas a physical architecture may include various permutations, combinations, and/or hybrids of these elements. Countless possible design configurations can be used to achieve the operational objectives outlined herein. Accordingly, the associated infrastructure has a myriad of substitute arrangements, design choices, device possibilities, hardware configurations, software implementations, and equipment options.

References may be made herein to a computer-readable medium, which may be a tangible and non-transitory computer-readable medium. As used in this specification and throughout the claims, a “computer-readable medium” should be understood to include one or more computer-readable mediums of the same or different types. A computer-readable medium may include, by way of nonlimiting example, an optical drive (e.g., CD/DVD/Blu-Ray), a hard drive, a solid state drive, a flash memory, or other non-volatile medium. A computer-readable medium could also include a medium such as a ROM, an FPGA or ASIC configured to carry out the desired instructions, stored instructions for programming an FPGA or ASIC to carry out the desired instructions, an intellectual property (IP) block that can be integrated in hardware into other circuits, or instructions encoded directly into hardware or microcode on a processor such as a microprocessor, DSP, microcontroller, or in any other suitable component, device, element, or object where appropriate and based on particular needs. A non-transitory storage medium herein is expressly intended to include any non-transitory special-purpose or programmable hardware configured to provide the disclosed operations, or to cause a processor to perform the disclosed operations.

Various elements may be “communicatively,” “electrically,” “mechanically,” or otherwise “coupled” to one another throughout this specification and the claims. Such coupling may be a direct, point-to-point coupling, or may include intermediary devices. For example, two devices may be communicatively coupled to one another via a controller that facilitates the communication. Devices may be electrically coupled to one another via intermediary devices such as signal boosters, voltage dividers, or buffers. Mechanically coupled devices may be indirectly mechanically coupled.

Any “module” or “engine” disclosed herein may refer to or include software, a software stack, a combination of hardware, firmware, and/or software, a circuit configured to carry out the function of the engine or module, or any computer-readable medium as disclosed above. Such modules or engines may, in appropriate circumstances, be provided on or in conjunction with a hardware platform, which may include hardware compute resources such as a processor, memory, storage, interconnects, networks and network interfaces, accelerators, or other suitable hardware. Such a hardware platform may be provided as a single monolithic device (e.g., in a PC form factor), or with some or part of the function being distributed (e.g., a “composite node” in a high-end data center, where compute, memory, storage, and other resources may be dynamically allocated and need not be local to one another).

There may be disclosed herein flow charts, signal flow diagram, or other illustrations showing operations being performed in a particular order. Unless otherwise expressly noted, or unless required in a particular context, the order should be understood to be a nonlimiting example only. Furthermore, in cases where one operation is shown to follow another, other intervening operations may also occur, which may be related or unrelated. Some operations may also be performed simultaneously or in parallel. In cases where an operation is said to be “based on” or “according to” another item or operation, this should be understood to imply that the operation is based at least partly on or according at least partly to the other item or operation. This should not be construed to imply that the operation is based solely or exclusively on, or solely or exclusively according to the item or operation.

All or part of any hardware element disclosed herein may readily be provided in an SoC, including a CPU package. An SoC represents an IC that integrates components of a computer or other electronic system into a single chip. Thus, for example, client devices or server devices may be provided, in whole or in part, in an SoC. The SoC may contain digital, analog, mixed-signal, and radio frequency functions, all of which may be provided on a single chip substrate. Other embodiments may include a multichip module (MCM), with a plurality of chips located within a single electronic package and configured to interact closely with each other through the electronic package.

In a general sense, any suitably-configured circuit or processor can execute any type of instructions associated with the data to achieve the operations detailed herein. Any processor disclosed herein could transform an element or an article (for example, data) from one state or thing to another state or thing. Furthermore, the information being tracked, sent, received, or stored in a processor could be provided in any database, register, table, cache, queue, control list, or storage structure, based on particular needs and implementations, all of which could be referenced in any suitable timeframe. Any of the memory or storage elements disclosed herein, should be construed as being encompassed within the broad terms “memory” and “storage,” as appropriate.

Computer program logic implementing all or part of the functionality described herein is embodied in various forms, including, but in no way limited to, a source code form, a computer executable form, machine instructions or microcode, programmable hardware, and various intermediate forms (for example, forms generated by an assembler, compiler, linker, or locator). In an example, source code includes a series of computer program instructions implemented in various programming languages, such as an object code, an assembly language, or a high level language such as OpenCL, FORTRAN, C, C++, JAVA, or HTML for use with various operating systems or operating environments, or in hardware description languages such as Spice, Verilog, and VHDL. The source code may define and use various data structures and communication messages. The source code may be in a computer executable form (e.g., via an interpreter), or the source code may be converted (e.g., via a translator, assembler, or compiler) into a computer executable form, or converted to an intermediate form such as byte code. Where appropriate, any of the foregoing may be used to build or describe appropriate discrete or integrated circuits, whether sequential, combinatorial, state machines, or otherwise.

In one example embodiment, any number of electrical circuits of the FIGURES may be implemented on a board of an associated electronic device. The board can be a general circuit board that can hold various components of the internal electronic system of the electronic device and, further, provide connectors for other peripherals. Any suitable processor and memory can be suitably coupled to the board based on particular configuration needs, processing demands, and computing designs. Note that with the numerous examples provided herein, interaction may be described in terms of two, three, four, or more electrical components. However, this has been done for purposes of clarity and example only. It should be appreciated that the system can be consolidated or reconfigured in any suitable manner. Along similar design alternatives, any of the illustrated components, modules, and elements of the FIGURES may be combined in various possible configurations, all of which are within the broad scope of this specification.

Numerous other changes, substitutions, variations, alterations, and modifications may be ascertained to one skilled in the art and it is intended that the present disclosure encompass all such changes, substitutions, variations, alterations, and modifications as falling within the scope of the appended claims.

In order to assist the United States Patent and Trademark Office (USPTO) and, additionally, any readers of any patent issued on this application in interpreting the claims appended hereto, Applicant wishes to note that the Applicant: (a) does not intend any of the appended claims to invoke paragraph six (6) of 35 U.S.C. section 112 (pre-AIA) or paragraph (f) of the same section (post-AIA), as it exists on the date of the filing hereof unless the words “means for” or “steps for” are specifically used in the particular claims; and (b) does not intend, by any statement in the specification, to limit this disclosure in any way that is not otherwise expressly reflected in the appended claims.

### EXAMPLE IMPLEMENTATIONS

The following examples are provided by way of illustration.

Example 1 includes a fiberoptic communication circuit for wavelength division multiplexing (WDM) communication, comprising: an incoming waveguide to receive an incoming WDM laser pulse; an intermediate slab comprising a demultiplexer circuit to isolate n discrete modes from the incoming WDM laser pulse; n outgoing waveguides to receive the n discrete modes, the outgoing waveguides comprising fully-etched rib-to-channel waveguides; and an array of n photodetectors to detect the n discrete modes.

Example 2 includes the fiberoptic communication circuit of example 1, wherein the incoming waveguide comprises a fully-etched rib-to-channel waveguide.

Example 3 includes the fiberoptic communication circuit of example 1, comprising a rib-to-channel converter at the incoming waveguide.

Example 4 includes the fiberoptic communication circuit of example 3, comprising an echelle grating at the incoming waveguide.

Example 5 includes the fiberoptic communication circuit of example 4, wherein the rib-to-channel converter is located at the echelle grating.

Example 6 includes the fiberoptic communication circuit of any of examples 3-5, wherein the rib-to-channel converter comprises a rib, a rib-channel overlapping region, and a channel waveguide.

Example 7 includes the fiberoptic communication circuit of example 1, comprising rib-to-channel converters at the incoming waveguide and at the outgoing waveguides.

Example 8 includes the fiberoptic communication circuit of example 6, wherein the rib-to-channel converter comprises a rib, a rib-channel overlapping region, and a fully-etched channel waveguide.

Example 9 includes an integrated circuit to provide (WDM) communication for a system-on-a-chip, comprising: an input-side waveguide to receive a multiplexed laser pulse; a demultiplexer circuit configured to isolate n discrete carrier wavelengths from the multiplexed laser pulse; and n output-side waveguides to direct the n discrete carrier wavelengths to n photodetectors, the outgoing waveguides comprising fully-etched channel waveguides; wherein at least one of the input-side waveguide or the output-side waveguides comprise one or more rib-to-channel converters.

Example 10 includes the integrated circuit of example 9, wherein the input-side waveguide comprises a fully-etched channel waveguide.

Example 11 includes the integrated circuit of example 9, comprising a rib-to-channel converter at the input-side waveguide.

Example 12 includes the integrated circuit of example 11, comprising an echelle grating at the input-side waveguide.

Example 13 includes the integrated circuit of example 12, wherein the rib-to-channel converter is located at the echelle grating.

Example 14 includes the integrated circuit of example 9, comprising rib-to-channel converters at the output-side waveguides.

Example 15 includes the integrated circuit of example 9, comprising rib-to-channel converters at both the input-side and output-side waveguides.

Example 16 includes the integrated circuit of any of examples 9-15, wherein the rib-to-channel converter comprises a rib, a rib-channel overlapping region, and a fully-etched channel waveguide.

Example 17 includes a method of manufacturing a demultiplexer having at least one rib-to-channel converter, comprising: etching channel waveguides into a semiconductor substrate; filling the channel waveguides with a cladding film; planarizing; etching rib waveguides into the substrate along trenches of the channels; filling rib trenches with cladding film; and planarizing.

Example 18 includes the method of example 17, wherein the semiconductor substrate is a silicon substrate comprising silicon-on-insulator and a dielectric material.

Example 19 includes the method of example 17, wherein the semiconductor substrate is a Si₃N₄ substrate, further comprising a semiconductor layer comprising a dielectric material.

Example 20 includes the method of example 17, wherein the method employs a high aspect ratio deposition process.

What is claimed is:

1. A fiberoptic communication circuit for wavelength division multiplexing (WDM) communication, comprising:
an incoming waveguide to receive an incoming WDM laser pulse;
an intermediate slab comprising a demultiplexer circuit to isolate n discrete modes from the incoming WDM laser pulse;
n outgoing waveguides to receive the n discrete modes, the outgoing waveguides comprising fully-etched rib-to-channel waveguides; and
an array of n photodetectors to detect the n discrete modes.

2. The fiberoptic communication circuit of claim 1, wherein the incoming waveguide comprises a fully-etched rib-to-channel waveguide.

3. The fiberoptic communication circuit of claim 1, comprising a rib-to-channel converter at the incoming waveguide.

4. The fiberoptic communication circuit of claim 3, comprising an echelle grating at the incoming waveguide.

5. The fiberoptic communication circuit of claim 4, wherein the rib-to-channel converter is located at the echelle grating.

6. The fiberoptic communication circuit of claim 3, wherein the rib-to-channel converter comprises a rib, a rib-channel overlapping region, and a channel waveguide.

7. The fiberoptic communication circuit of claim 1, comprising rib-to-channel converters at the incoming waveguide and at the outgoing waveguides.

8. The fiberoptic communication circuit of claim 6, wherein the rib-to-channel converter comprises a rib, a rib-channel overlapping region, and a fully-etched channel waveguide.

9. An integrated circuit to provide (WDM) communication for a system-on-a-chip, comprising:
an input-side waveguide to receive a multiplexed laser pulse;
a demultiplexer circuit configured to isolate n discrete carrier wavelengths from the multiplexed laser pulse; and
n output-side waveguides to direct the n discrete carrier wavelengths to n photodetectors, the outgoing waveguides comprising fully-etched channel waveguides;
wherein at least one of the input-side waveguide or the output-side waveguides comprise one or more rib-to-channel converters.

10. The integrated circuit of claim 9, wherein the input-side waveguide comprises a fully-etched channel waveguide.

11. The integrated circuit of claim 9, comprising a rib-to-channel converter at the input-side waveguide.

12. The integrated circuit of claim 11, comprising an echelle grating at the input-side waveguide.

13. The integrated circuit of claim 12, wherein the rib-to-channel converter is located at the echelle grating.

14. The integrated circuit of claim 9, comprising rib-to-channel converters at the output-side waveguides.

15. The integrated circuit of claim 9, comprising rib-to-channel converters at both the input-side and output-side waveguides.

16. The integrated circuit of claim 9, wherein the rib-to-channel converter comprises a rib, a rib-channel overlapping region, and a fully-etched channel waveguide.

17. A method of manufacturing a demultiplexer having at least one rib-to-channel converter, comprising:
etching channel waveguides into a semiconductor substrate;
filling the channel waveguides with a cladding film;
planarizing;
etching rib waveguides into the substrate along trenches of the channels;
filling rib trenches with cladding film; and
planarizing.

18. The method of claim 17, wherein the semiconductor substrate is a silicon substrate comprising silicon-on-insulator and a dielectric material.

19. The method of claim 17, wherein the semiconductor substrate is a Si₃N₄ substrate, further comprising a semiconductor layer comprising a dielectric material.

20. The method of claim 17, wherein the method employs a high aspect ratio deposition process.
